(19) United States
(12) Patent Application Publication
(10) Pub. No.: US 2014/0167577 A1
(43) Pub. Date: Jun. 19, 2014

(54) CAGE FOR HARD DISK DRIVE AND ELECTRONIC DEVICE USING THE CAGE

(71) Applicant: HON HAI PRECISION INDUSTRY CO., LTD., New Taipei (TW)

(72) Inventors: TSAI-YIN FANG, New Taipei (TW); CHAO-TANG WANG, New Taipei (TW)

(73) Assignee: HON HAI PRECISION INDUSTRY CO., LTD., New Taipei (TW)

(21) Appl. No.: 13/730,620

(22) Filed: Dec. 28, 2012

(30) Foreign Application Priority Data
Dec. 19, 2012 (CN) 201210554202.1

(51) Int. Cl. H05K 7/14

(52) U.S. Cl. CPC H05K 7/14
USPC 312/223.2

(57) ABSTRACT

A cage for hard disk drives includes left and right sidewalls parallel with each other, and a front wall perpendicularly connected between front sides of the left and right sidewalls. A receiving space is bound by the left sidewall, the right sidewall, and the front wall. The front wall defines a number of openings, through which the hard disk drives slide into or out of the cage. The cage further includes a reinforcing bracket fixed to an outside of the right sidewall. The reinforcing bracket includes a fixing flange abutting the right sidewall, and a middle plate perpendicularly extending from the fixing flange away from the right sidewall.

### BACKGROUND

1. Technical Field

The present disclosure relates to a cage for mounting a plurality of hard disk drives.

2. Description of Related Art

Electronic devices, such as severs, include one or more hard disk drives (HDDs), which will cause vibration and noise. Traditionally, the HDDs are accommodated in a cage made of thin metal sheets. Therefore, if the structure of the acge is weak, walls of the cage may resonate as the HDDs vibrate, which will intensifies the noise.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an isometric, exploded view of an exemplary embodiment of a cage and a chassis.

FIG. 2 is a side plan view of the an electronic device including the age and a chassis of FIG. 1, and a plurality of hard disk drives received in the cage.

### DETAILED DESCRIPTION

The disclosure, including the accompanying drawings, is illustrated by way of examples and not by way of limitation. It should be noted that references to “an” or “one” embodiment in this disclosure are not necessarily to the same embodiment, and such references mean at least one.

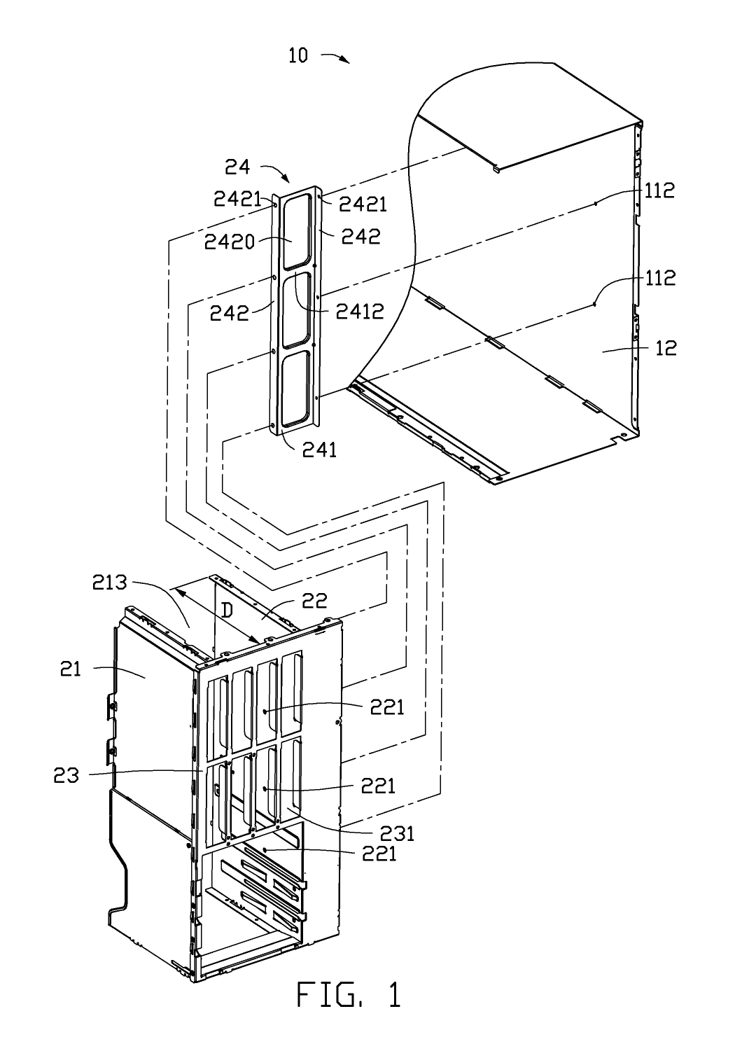

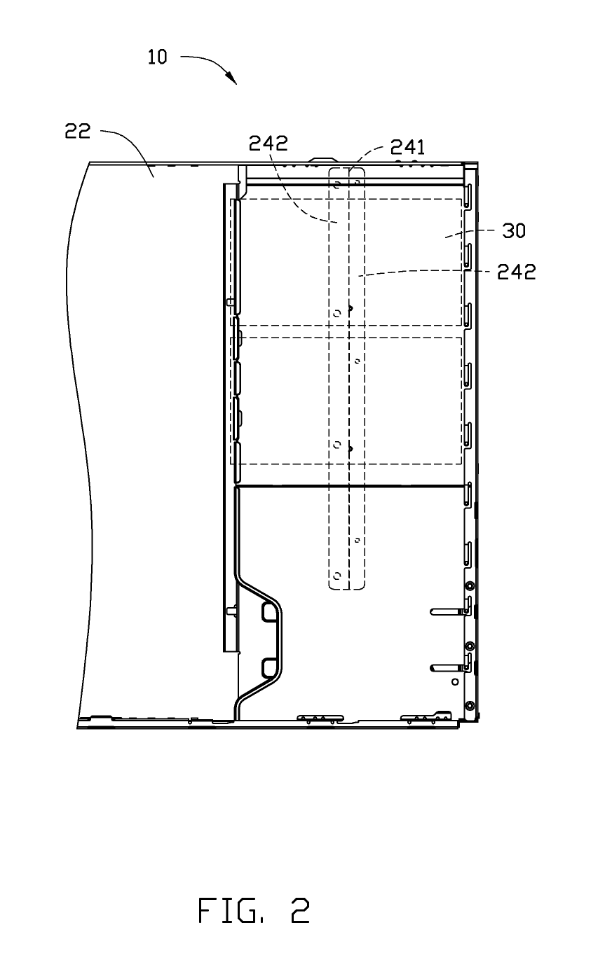

FIGS. 1 and 2 show an exemplary embodiment of a cage, mounted in a chassis 10 for accommodating a plurality of HDDs 30.

The cage includes a left sidewalls 21, a right sidewall 22 parallel to the left sidewall 21, a front wall 23 connected between front ends of the left and right sidewalls 21 and 22, and a reinforcing bracket 24. The front wall 23 defines a plurality of openings 231, arranged from top to bottom. The openings 231 communicate with an inner space 213, which is bounded by the left sidewall 21, the right sidewall 22, and the front wall 23. A depth D of the inner space 213 is substantially equal to a length of each of the HDDs 30. The right sidewall 22 defines a plurality of fastening holes 221.

The reinforcing bracket 24 includes a rectangular middle plate 241 and two fixing flanges 242 perpendicularly extending from opposite sides of the middle plate 241 along opposite directions, respectively. The middle plate 241 defines a plurality of through holes 2420. A supporting bar 2412 is connected between opposite sides of the middle plate 241, between every two adjacent through holes 2420. Each of the fixing flanges 242 defines a plurality of fixing holes 2421 along a longwise direction of the fixing flange 242.

The chassis 10 includes a right plate 12, which defines a plurality of fastening holes 112.

In assembly, the reinforcing bracket 24 is fixed between the right sidewall 22 and the right plate 12 of the chassis 10, with a plurality of fasteners, such as screws or rivets, extending through the fixing holes 2421 of the two flanges 242 and correspondingly fastens in the fastening holes 221 of the right sidewall 22 and the fastening holes 112 of the side plate 12. The middle plate 241 of the reinforcing bracket 24 is perpendicular to the right sidewall 22. A distance between the middle plate 241 and the front wall 23 is substantially equal to a half of the depth D of the inner space 213.

In use, the HDDs 30 are inserted into the inner space 213 through the corresponding openings 231. A distance between the middle plate 241 and a front end of each of the HDDs 30 is substantially equal to a distance between the middle plate 241 and a rear end of the HDD 30. The cage is stabilized and is prevented from resonating with the HDDs 30 due to the reinforcing bracket 24.

It is to be understood, however, that even though numerous characteristics and advantages of the embodiment have been set forth in the foregoing description, together with details of the structure and function of the embodiment, the disclosure is illustrative only, and changes may be made in detail, especially in the matters of shape, size, and arrangement of parts within the principles of the present disclosure to the full extent indicated by the broad general meaning of the terms in which the appended claims are expressed.

1. A cage for receiving one or more hard disk drives (HDDs), comprising:
a first sidewall;
a second sidewall parallel to the first sidewall;
a front wall connected between front ends of the first and second sidewalls, and defining a plurality of openings communicating with an inner space bounded by the first sidewall, the second sidewall, and the front wall; and
a reinforcing bracket having a first bracket end and a second bracket end, the reinforcing bracket fixed to an outside of the second sidewall and supported substantially along its entire length between the first bracket end and the second bracket end.

2. The cage of claim 1, wherein the reinforcing bracket comprises a fixing flange abut the second sidewall, and a middle plate extending from the fixing flange, and the middle plate is perpendicular to the second sidewall, a distance between the middle plate and the front wall is substantially equal to a half of a depth of the inner space.

3. An electronic device, comprising:
a chassis comprising a second plate;
a cage fixed in the chassis and comprising:
a first sidewall;
a second sidewall parallel to the first sidewall;
a front wall connected between front ends of the first and second sidewalls, and defining a plurality of openings communicating with an inner space bounded by the first sidewall, the second sidewall, and the front wall; and
a reinforcing bracket fixed between the second sidewall of the cage and the second plate of the chassis, the reinforcing bracket having first and second sides, whereby substantially the entire first side contacts the cage and substantially the entire second side contacts the second plate of the chassis; and
a plurality of hard disk drives received in the inner space of the cage, and capable of moving out of the cage through the corresponding openings of the front wall.

4. The electronic device of claim 3, wherein the reinforcing bracket comprises two fixing flanges, one fixing flange corresponding to the first bracket side and the other fixing flange corresponding to the second bracket side, whereby the fixing flanges respectively abutting the second sidewall of the cage and the second plate of the chassis, and a middle plate perpendicularly connected between the fixing flanges.

5. The electronic device of claim 4, wherein a distance between the middle plate and a front end of each of the HDDs is substantially equal to a distance between the middle plate and a rear end of the HDD.
